(19) United States
(12) Patent Application Publication
(10) Pub. No.: US 2015/0293192 A1
(43) Pub. Date: Oct. 15, 2015

(54) METHOD AND APPRATUS FOR SUPPRESSING ELECTROMAGNETIC FIELDS INDUCED BY A MAGNETIC RESONANCE IMAGING SYSTEM IN ELECTRONIC CABLES AND DEVICES

(71) Applicant: BRIGHAM AND WOMEN'S HOSPITAL, INC., Boston, MA (US)

(72) Inventors: Ehud J. Schmidt, Newton, MA (US); Tsz Ho Tse, Brighton, MA (US); Samuel Patz, Chestnut Hill, MA (US); Charles L. Dumoulin, Cincinnati, OH (US)

(21) Appl. No.: 14/439,417

(22) PCT Filed: Nov. 1, 2013
(86) PCT No.: PCT/US13/67931

§ 371 Date: Apr. 29, 2015

Related U.S. Application Data
(60) Provisional application No. 61/721,891, filed on Nov. 2, 2012.

(51) Int. Cl. G01R 33/42; H01F 1/00; H01B 11/18; G01R 33/36; G01R 33/34

(52) U.S. Cl. CPC G01R 33/42; G01R 33/36; G01R 33/34092; H01B 11/1895; H01F 1/0018

(57) ABSTRACT

A method and apparatus for suppressing electromagnetic fields induced in cables and electronic medical devices by a magnetic resonance imaging (“MRI”) system are provided. The apparatus includes a cable assembly constructed as a conductive wire wrapped around a paramagnetic core. The paramagnetic core may include a tube filled with a paramagnetic material, such as a gadolinium-based solution or a liquid in which iron oxide particles are suspended.

### CROSS-REFERENCE TO RELATED APPLICATIONS

This application is based on, claims priority to, and incorporates herein by reference in its entirety U.S. Provisional Application Ser. No. 61/721,891, entitled “Method and Apparatus for Suppressing Electromagnetic Fields Induced by a Magnetic Resonance Imaging System in Electronic Cables and Devices,” filed Nov. 2, 2013.

### BACKGROUND OF THE INVENTION

The field of the invention is systems and methods for magnetic resonance imaging (“MRI”). More particularly, the invention relates to systems and methods for suppressing electromagnetic fields induced in cables and electronic devices located in proximity to or within an MRI system.

Conductive wires, both single conductor and coaxial cables, are commonly used to transmit signals that carry important content between two or more spatial positions. Each signal has a characteristic current amplitude, frequency content, and temporal shape. When a conductive wire is placed in an alternating electromagnetic (“EM”) field, a current or voltage is induced in that wire by the EM field. As a result, the induced currents or voltages will be superimposed on the original signal being transmitted on that wire. The induced currents or voltages constitute electromagnetic interference (“EMI”) that manifests as noise in the original signal, making it difficult to distinguish the original signal from the induced currents or voltages.

One situation where it is especially difficult to recover information corrupted by EMI is when the conducting wire is connected to a digital receiver. Digital receivers use an analog-to-digital converter (“ADC”) that has a user-defined acceptance range of input signal intensities (voltages or currents). If the added noise coming from the EMI results in an input signal intensity that exceeds the maximal value of the ADC's acceptance range, then the ADC output signal will be set at the maximum allowed level; that is, the signal is “clipped.” As a consequence, it may be impossible to recover the original signal because information in the original signal may have been partially or completely removed by the receiving ADC.

In addition to the issue of data recognition, the induced currents, if sufficiently large, can damage the wire or circuitry to which the wire is connected because the summation of the induced and original currents can exceed the operating specifications of the wire or receiving electronics. Exceeding these limits can lead to safety issues, such as wire and equipment failure, skins burns, and so on.

A special case of induced currents occurs in coaxial cables. Normally, when current is sent from one point to another on a coaxial cable, the inner conductor has current flowing in one direction, while the outer conductor (the return path) has current flowing in the opposite direction. Such flow in the coaxial cable is called the differential mode and represents the intended use of this cable. When currents are induced on a coaxial cable from outside sources a frequent occurrence is the excitation of another mode in the coaxial cable, the common mode. In the common mode, the current flow on the inner and outer conductor is in the same direction. Common mode induced currents are a frequent cause of both noise and safety issues in medical applications. One reason why the common mode is more dangerous than the differential mode is that it is typically a higher-frequency signal. Higher-frequency EM waves travel preferentially In a limited thickness layer on the surface of the wire (the “skin depth”), rather than throughout the conductor's cross-section. As a result, there is a concentration of current in a far smaller cross-sectional area, which leads to increased heating because there is effectively a higher resistance to current flow.

One common way to suppress EMI in conductive wires, such as coaxial cables, is to use ferrite chokes. Ferrite chokes are an inexpensive and frequently used solution to the above issues resulting from induced EM waves. Ferrite chokes are usually constructed from ferromagnetic materials, such as mixtures of Iron oxide and one or more metals, typically manganese, nickel, and zinc. Occasionally, rare earth materials, such as yttrium and scandium are also added. Materials used in ferrites are generally called “soft magnets,” which means they have a high magnetic susceptibility, as well as relatively large energy dissipation in an alternating current magnetic field. Ferrites are primarily used with their magnetic domains Initially non-magnetized. Ferrites commonly come in the form of a split into-two (along-its-length) cylindrical shape, a bead shaped object with a central hole, or a doughnut shaped object. In such configurations, the electrical cable is wound around the ferrite, sometimes using multiple turns, which can increase the ferrite's attenuating effect at the expense of the ferrite's effectiveness to a lower frequency range.

When a single conductor cable is wound around a ferrite, the current flowing in the cable creates a magnetic field inside the ferrite core, and this magnetic field attempts to reorient the magnetic domains inside the ferrite. This attempted reorientation dissipates heat and attenuates the driving magnetic field, which reduces the current in the cable.

When a ferrite is used with a coaxial cable, the differential mode causes equal, but opposing, fields inside the ferrite. As a result, very little dissipation occurs. On the other hand, the common mode creates a large net field inside the ferrite, so a great deal of dissipation occurs. As a result of these effects, the common mode is strongly attenuated, leaving the differential mode relatively untouched. Thus, it is common to find ferrite beads or cylinders mounted in several positions on electrical cables when these cables traverse regions of high EMI, such as regions of high radio frequency interference (“RFI”). Ferrite beads and/or cylinders are inexpensive and are easy to mount on any cable, so a common practice to avoid EMI is to place ferrites in regions where large EM fields are expected to be found. Such regions may include regions having periodic maxima of a standing wave, areas of poor or incomplete cable shielding, areas of maximum RFI, and so on. Another common location to place ferrites is immediately at the end of a cable before it goes into a receiver. In this way, the ferrite “chokes” the common mode induced current immediately before the receiver and does not allow for further pick up of undesirable RFI.

Many electrical cables currently lead from outside the bore of an MRI scanner into the bore. Such cables include ECG lead cables, cables connecting to defibrillation pads, various monitoring cables (SPO2, strain, etc.), radio frequency ablation cables, as well as cables required for RF coils used during an MRI scan. Placing cables inside the MRI environment makes the system susceptible to multiple issues.

One issue is that cables made with ferromagnetic components may be physically displaced by the strong magnetic field of the MRI system. This effect restricts the types of cables used inside an MRI system to those that are “MRI safe,” which is to say that they are not physically displaced by the magnet. This effect also restricts the use of conventional ferrites on cables in the proximity of an MRI system's static magnetic field because the ferrites would be pulled into the magnetic field, which potentially creates safety issues because people in or near the MRI scanner could be injured as a result of the object being pulled by the magnetic field. In addition, the efficiency of conventional ferrites would be substantially reduced inside the bore of the MRI system because the magnetic domains in a ferromagnetic material are mostly saturated in the MRI system's strong static magnetic field, thereby resulting in a reduced magnetic susceptibility in the ferrite. Thus, the response of a conventional ferrite in an MRI system would be much smaller than if the ferrite was in a low magnetic field. This would result in only a small amount of energy being dissipated, thereby resulting in the ferrite ceasing to function properly.

Another issue is that the magnetic field gradients used during an MRI scan may induce EM waves in the cables or electronic devices. These induced waves are generally in the 20 Hz-9 kHz frequency range. As a result of these gradient-induced EM waves, cables traversing within or near an MRI system receive Induced EM signals that manifest as EMI. In coaxial cables, where the wavelength of the EMI signal is much greater than the diameter of cable, induced currents are mostly common-mode signals. This condition is valid for frequencies up to several GHz for cable diameters up to 10 mm. Gradient-induced EM waves are a big problem for ECG leads, since the Induced waves can be as much as 100 times stronger than the surface ECG signals. Moreover, such induced EM waves are in the same frequency band as the ECG signals, which typically include spectral components in the 0.5-500 Hz frequency range. It is, therefore, difficult to separate the real ECG signal from the Induced noise.

Still another issue is that the RF excitation pulses generated during an MRI scan may induce EM waves in the cables or electronic devices. The EM waves Induced by the RF excitation pulses are generally at or near the Larmor frequency, which is typically 64-127 MHz. RF-induced EM waves pose a significant safety Issue because the induced currents and voltages scale with frequency and these induced waves are at a relatively high frequency (the Larmor frequency). In addition, the wavelength decreases with increasing frequency, so higher frequency EM waves couple to the relatively thin cables more efficiently than lower frequency waves. A common MRI RF amplifier delivers between 15-35 kilowatt power in every RF pulse. Thus, even a small fraction of this power, if it travels on an ECG lead, can potentially cause surface burns in areas of high resistance, such as at the ECG electrodes on the surface of the patient's body.

Thus, there is a need to provide a method and apparatus for suppressing EMI, and gradient-induced and RF-induced EM waves in general, in cables and electronic devices positioned within or near an MRI system. Preferably, such a solution would be less complex and less expensive than RF traps, such as baluns. In addition, baluns generally attenuate only a specific frequency, so it would also be preferable to provide a solution for suppressing induced EM fields that can attenuate a larger band of frequencies. Moreover, preferably this solution would also be independent of magnetic field strength.

### SUMMARY OF THE INVENTION

The present invention overcomes the aforementioned drawbacks by providing a cable assembly for suppressing electromagnetic fields induced by a magnetic resonance imaging (“MRI”) system in a cable or electronic device. The cable assembly includes a paramagnetic core extending along a longitudinal axis from a proximal end to a distal end, and a conductive wire wrapped around the paramagnetic core from the proximal end of the paramagnetic core to the distal end of the paramagnetic core. The paramagnetic core may include a tube filled with a paramagnetic material, such as a solution containing gadolinium or iron oxide particles in a liquid suspension.

The foregoing and other aspects and advantages of the invention will appear from the following description. In the description, reference is made to the accompanying drawings which form a part hereof, and in which there is shown by way of illustration a preferred embodiment of the invention. Such embodiment does not necessarily represent the full scope of the invention, however, and reference is made therefore to the claims and herein for Interpreting the scope of the invention.

### BRIEF DESCRIPTION OF THE DRAWINGS

FIG. 1 is an example of a cable assembly for suppressing electromagnetic fields induced by a magnetic resonance imaging (“MRI” system;

FIG. 2 is a cross-section of a paramagnetic core that forms a part of the cable assembly of FIG. 1;

FIG. 3 is an example of a paramagnetic core that includes a ring-shaped enclosure;

FIG. 4 is a cross-section of the paramagnetic core of FIG. 3;

FIG. 5 is an example of a paramagnetic core that includes an annular enclosure;

FIG. 6 is a cross-section of the paramagnetic core of FIG. 5; and

FIG. 7 is a block diagram of an example of an MRI system.

### DETAILED DESCRIPTION OF THE INVENTION

A method and apparatus for suppressing electromagnetic (“EM”) fields induced in conductive wires and cables and in electronic devices by EM fields generated by a magnetic resonance imaging (“MRI”) system are provided. In general, a cable assembly having a paramagnetic core is provided to achieve suppression of EM fields induced in electronic cables and devices by the EM fields generated by an MRI system. It is contemplated that the cable assembly will provide a significant reduction in induced currents and voltages as compared to unshielded cables and electronic devices. For instance, it is contemplated that the cable assembly can provide upwards of at least a ninety-five percent reduction in induced currents and voltages. Additional benefits of the cable assembly of the present invention include its ease of use and low cost relative to current MRI-compatible EM field and EM interference (“EMI”) suppression solutions. As an example of the cable assembly's ease of use, the cable assembly does not need to be tailored to a specific Larmor frequency, unlike other MRI-compatible EMI suppression solutions. As an example of the cable assembly's low cost, the cable assembly is considerably less expensive to construct than the baluns often used in radio frequency (“RF”) coils.

The cable assembly of the present invention may be viewed as a nonmagnetic “ferrite” that can be used inside the magnetic field environment of an MRI system. The cable assembly is as effective as traditional ferromagnetic ferrites, but is MRI-compatible, unlike ferromagnetic ferrites. The cable assembly makes use of a strongly paramagnetic material, such as gadolinium or iron oxides, in the form of powders or liquid emulsions, to perform the same function that ferromagnetic materials play in conventional ferrites.

The benefits of the nonmagnetic “ferrite” cable assembly include the following. The cable assembly can be used safely within and in close proximity to an MRI scanner. The magnetic moment of the cable assembly does not saturate in the magnetic field, B₀, of the MRI system; rather, it continues to grow linearly with the strength of the magnetic field, B₀. This lack of saturation means that the cable assembly is as effective inside the bore of the MRI scanner as it is outside the bore.

The cable assembly of the present invention may be implemented in a broad range of different devices. Some examples of the cable assembly's use are as follows. The cable assembly may be used to construct a safe and undistorted electrocardiography system capable of operating inside the bore of an MRI system. For instance, the cable assembly could be used to construct 12-lead ECG systems, which are conventionally vulnerable to EMI without appropriate protections. The cable assembly may also be used to construct defibrillation pads that can be placed permanently on an ischemic cardiac patient so that such a patient can be safely scanned using an MRI system. The cable assembly may also be used to construct a cardiac electrophysiology RF ablation catheters, which may then be safely used within the heart of a patient while they are inside the bore of an MRI system and while the MRI is being used to scan the patient.

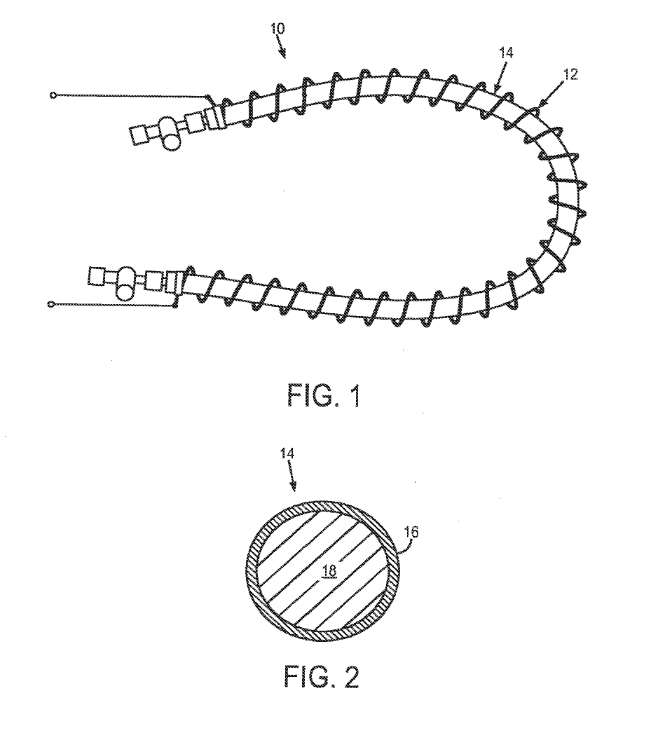

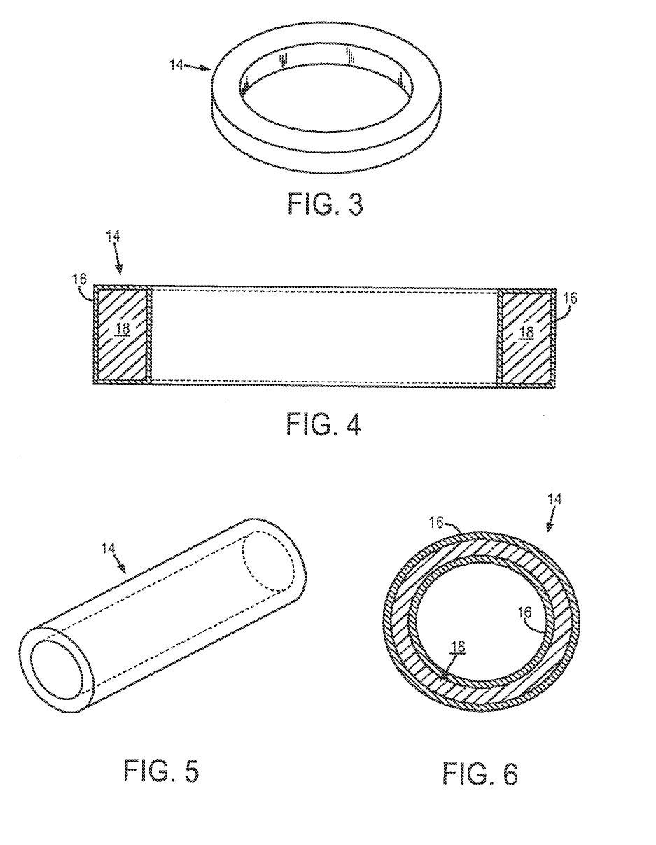

Referring now to FIGS. 1 and 2, the cable assembly 10 of the present invention includes a conductive wire 12 proximal to a paramagnetic core 14. The conductive wire 12 may include a single conductor wire or a two conductor wire, such as a coaxial cable. Also, the conductive wire 12 may include more than one wire or cable. Generally, the paramagnetic core 14 includes an enclosure 16 that is filled with a paramagnetic material 18. By way of example, the paramagnetic core 14 may include an enclosure 16 that is a tube filled with a paramagnetic material 18. In this example, the enclosure 16 is preferably a tube composed of nonmagnetic materials, such as a plastic. For instance, the enclosure 16 may be a Tygon® (Saint-Gobain, S.A.; Courbevoie, France) tube. The enclosure 16 may also be a ring, such as a toroid, as illustrated in FIGS. 3 and 4, or an annular enclosure, as illustrated in FIGS. 5 and 6. The conductive wire 12, may then either be wrapped around the surface of the paramagnetic core 14, or may extend through a portion of the paramagnetic core 14, such as through the center bore of an annular enclosure.

The paramagnetic material 18 may include a gadolinium chelate solution, such as a readily available gadolinium-based magnetic resonance contrast agent. Examples of gadolinium-based contrast agents include Gd-DPTA contrast agents, such as the Gd-DTPA contrast agent marketed as MAGNEVIST® (Bayer HealthCare Pharmaceuticals Inc., Montville, N.J.). The paramagnetic material 18 may also include a gadolinium salt solution, in which gadolinium is present in the solution as a salt and not in its chelated form. When using a gadolinium salt rather than a gadolinium chelate, higher concentrations of gadolinium in the solution can be achieved. The paramagnetic material 18 may also be composed of iron oxide, such as superparamagnetic iron oxide (“SPIO”) particles, whether in a powdered form, an emulsion, or other liquid suspension. In some instances, the paramagnetic material 18 may include paramagnetic particles suspended in a viscous liquid. In this instance the paramagnetic core 14 will dissipate heat produced in the cable assembly 10, which allows the cable assembly 10 to be used even in the presence of large currents that could otherwise lead to cracking of a convention, ferromagnetic ferrite.

One example configuration of the cable assembly 10 may be designed as follows. The cable assembly 10 may include a paramagnetic core 14 constructed of a tube enclosure 16 that is thirty centimeters long with an external diameter of twelve millimeters. The tube enclosure 16 is then filled with a paramagnetic material 18 that includes a Gd-DPTA solution. The conductive wire 12 wrapped around the paramagnetic core 14 includes a coaxial cable with an external diameter of two millimeters. The wire 12 is wrapped around the paramagnetic core 14 such that there is a spacing of one centimeters between each adjacent loop of the wire 12. This spacing is beneficial for reducing parasitic capacitance between adjacent loops of the wire 12, and helps maximize the suppression of EMI in the wire 12.

The paramagnetic core 14 can be configured appropriately depending on the intended use of the cable assembly 10. In general, because the underlying effect in the cable assembly 10 is magnetic coupling to the paramagnetic core 14, the more turns there are in the conductive wire 12, and the more paramagnetic material 18 that is present in the paramagnetic core 14, the stronger the suppressive effect of the cable assembly will be. It is also noted that the electrical performance characteristics of the cable assembly 10 can be adjusted by changing the dimensions of the conductive wire 12, paramagnetic core 14, or both. For instance, in general, as the cross-sectional area of the paramagnetic core 14 decreases, the frequencies attenuated by the cable assembly 10 will increase.

As noted, the cable assembly 10 may be implemented in RF coils; implantable cardiac devices, such as pacemakers and implanted cardioverter-defibrillators; electrocardiograph (“ECG”) systems; electroencephalography (“EEG”) systems; deep brain stimulation (“DBS”) devices; transcranial magnetic stimulation (“TMS”) devices; diagnostic or Interventional electrophysiology catheters, including RF ablation catheters used to treat cardiac arrhythmias; and so on. It is also possible to implement the cable assembly 10 in the construction of MRI-compatible ultrasound systems. Such ultrasound systems would be useful for magnetic resonance guided focused ultrasound (“MRgFUS”) applications, or for magnetic resonance guided positioning of catheters and other medical devices.

When the conductive wire 12 in cable assembly 10 includes a coaxial cable, the cable assembly 10 is capable of preserving the differential mode, while reducing the common mode. Also, more generally, the cable assembly 10 is able to reduce heating at the tip of electronic devices that are constructed using the cable assembly 10 of the present invention. For instance, RF antennas constructed using the cable assembly 10 will experience less tip heating during an MRI scan than those RF antennas constructed without the cable assembly 10.

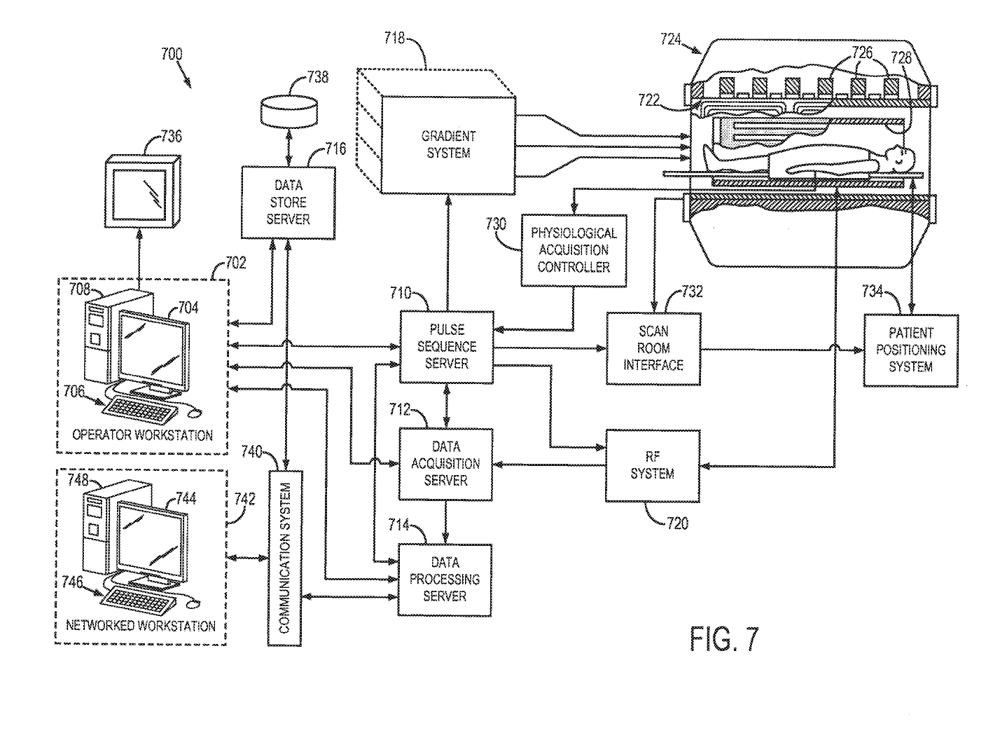

Referring particularly now to FIG. 7, an example of a magnetic resonance imaging (“MRI”) system 700 is illustrated. The MRI system 700 includes an operator workstation 702, which will typically include a display 704; one or more input devices 706, such as a keyboard and mouse; and a processor 708. The processor 708 may include a commercially available programmable machine running a commercially available operating system. The operator workstation 702 provides the operator interface that enables scan prescriptions to be entered into the MRI system 700. In general, the operator workstation 702 may be coupled to four servers: a pulse sequence server 710; a data acquisition server 712; a data processing server 714; and a data store server 716. The operator workstation 702 and each server 710, 712, 714, and 716 are connected to communicate with each other. For example, the servers 710, 712, 714, and 716 may be connected via a communication system 740, which may include any suitable network connection, whether wired, wireless, or a combination of both. As an example, the communication system 740 may include both proprietary or dedicated networks, as well as open networks, such as the internet.

The pulse sequence server 710 functions in response to instructions downloaded from the operator workstation 702 to operate a gradient system 718 and a radiofrequency (“RF”) system 720. Gradient waveforms necessary to perform the prescribed scan are produced and applied to the gradient system 718, which excites gradient coils in an assembly 722 to produce the magnetic field gradients Gₓ, G_{y}, and G_{z} used for position encoding magnetic resonance signals. The gradient coil assembly 722 forms part of a magnet assembly 724 that includes a polarizing magnet 726 and a whole-body RF coil 728.

RF waveforms are applied by the RF system 720 to the RF coil 728, or a separate local coil (not shown in FIG. 7), in order to perform the prescribed magnetic resonance pulse sequence. Responsive magnetic resonance signals detected by the RF coil 728, or a separate local coil (not shown in FIG. 7), are received by the RF system 720, where they are amplified, demodulated, filtered, and digitized under direction of commands produced by the pulse sequence server 710. The RF system 720 includes an RF transmitter for producing a wide variety of RF pulses used in MRI pulse sequences. The RF transmitter is responsive to the scan prescription and direction from the pulse sequence server 710 to produce RF pulses of the desired frequency, phase, and pulse amplitude waveform. The generated RF pulses may be applied to the whole-body RF coil 728 or to one or more local coils or coil arrays (not shown in FIG. 7).

The RF system 720 also Includes one or more RF receiver channels. Each RF receiver channel includes an RF preamplifier that amplifies the magnetic resonance signal received by the coil 728 to which it is connected, and a detector that detects and digitizes the I and Q quadrature components of the received magnetic resonance signal. The magnitude of the received magnetic resonance signal may, therefore, be determined at any sampled point by the square root of the sum of the squares of the I and Q components:

M=\sqrt{I²+Q²} (1);

and the phase of the received magnetic resonance signal may also be determined according to the following relationship:

$$ϕ = {tan}^{- 1} ( \frac{Q}{I} ) . \qquad ( 2 )$$

The pulse sequence server 710 also optionally receives patient data from a physiological acquisition controller 730. By way of example, the physiological acquisition controller 730 may receive signals from a number of different sensors connected to the patient, such as electrocardiograph (“ECG”) signals from electrodes, or respiratory signals from a respiratory bellows or other respiratory monitoring device. Such signals are typically used by the pulse sequence server 710 to synchronize, or “gate,” the performance of the scan with the subject's heart beat or respiration.

The pulse sequence server 710 also connects to a scan room interface circuit 732 that receives signals from various sensors associated with the condition of the patient and the magnet system. It is also through the scan room interface circuit 732 that a patient positioning system 734 receives commands to move the patient to desired positions during the scan.

The digitized magnetic resonance signal samples produced by the RF system 720 are received by the data acquisition server 712. The data acquisition server 712 operates in response to instructions downloaded from the operator workstation 702 to receive the real-time magnetic resonance data and provide buffer storage, such that no data is lost by data overrun. In some scans, the data acquisition server 712 does little more than pass the acquired magnetic resonance data to the data processor server 714. However, in scans that require information derived from acquired magnetic resonance data to control the further performance of the scan, the data acquisition server 712 is programmed to produce such information and convey it to the pulse sequence server 710. For example, during prescans, magnetic resonance data is acquired and used to calibrate the pulse sequence performed by the pulse sequence server 710. As another example, navigator signals may be acquired and used to adjust the operating parameters of the RF system 720 or the gradient system 718, or to control the view order in which k-space is sampled. In still another example, the data acquisition server 712 may also be employed to process magnetic resonance signals used to detect the arrival of a contrast agent in a magnetic resonance angiography (“MRA”) scan. By way of example, the data acquisition server 712 acquires magnetic resonance data and processes it in real-time to produce information that is used to control the scan.

The data processing server 714 receives magnetic resonance data from the data acquisition server 712 and processes it in accordance with instructions downloaded from the operator workstation 702. Such processing may, for example, include one or more of the following: reconstructing two-dimensional or three-dimensional images by performing a Fourier transformation of raw k-space data; performing other image reconstruction algorithms, such as iterative or backprojection reconstruction algorithms; applying filters to raw k-space data or to reconstructed images; generating functional magnetic resonance images; calculating motion or flow images; and so on.

Images reconstructed by the data processing server 714 are conveyed back to the operator workstation 702 where they are stored. Real-time images are stored in a data base memory cache (not shown in FIG. 7), from which they may be output to operator display 712 or a display 736 that is located near the magnet assembly 724 for use by attending physicians. Batch mode images or selected real time images are stored in a host database on disc storage 738. When such images have been reconstructed and transferred to storage, the data processing server 714 notifies the data store server 716 on the operator workstation 702. The operator workstation 702 may be used by an operator to archive the images, produce films, or send the Images via a network to other facilities.

The MRI system 700 may also include one or more networked workstations 742. By way of example, a networked workstation 742 may include a display 744; one or more input devices 746, such as a keyboard and mouse; and a processor 748. The networked workstation 742 may be located within the same facility as the operator workstation 702, or in a different facility, such as a different healthcare institution or clinic.

The networked workstation 742, whether within the same facility or in a different facility as the operator workstation 702, may gain remote access to the data processing server 714 or data store server 716 via the communication system 740. Accordingly, multiple networked workstations 742 may have access to the data processing server 714 and the data store server 716. In this manner, magnetic resonance data, reconstructed images, or other data may exchanged between the data processing server 714 or the data store server 716 and the networked workstations 742, such that the data or images may be remotely processed by a networked workstation 742. This data may be exchanged in any suitable format, such as in accordance with the transmission control protocol (“TCP”), the internet protocol (“IP”), or other known or suitable protocols.

The present invention has been described in terms of one or more preferred embodiments, and it should be appreciated that many equivalents, alternatives, variations, and modifications, aside from those expressly stated, are possible and within the scope of the invention.

1. A cable assembly for suppressing electromagnetic fields induced by a magnetic resonance imaging (MRI) system, comprising:
a paramagnetic core extending along a longitudinal axis from a proximal end to a distal end; and
at least one conductive wire wrapped around the paramagnetic core from the proximal end of the paramagnetic core to the distal end of the paramagnetic core.

2. The cable assembly as recited in claim 1 in which the paramagnetic core comprises a tube filled with a paramagnetic material.

3. The cable assembly as recited in claim 2 in which the paramagnetic material includes a solution containing gadolinium.

4. The cable assembly as recited in claim 2 in which the paramagnetic material includes iron oxide particles in a liquid suspension.

5. The cable assembly as recited in claim 1 in which the conductive wire is wrapped around the paramagnetic core such that adjacent loops of the conductive wire are spaced apart at a distance that minimized parasitic capacitance between the adjacent loops.

6. The cable assembly as recited in claim 1 further comprising a medical device in electrical communication with the conductive wire.

7. The cable assembly as recited in claim 6 in which the medical device includes at least one of an electrocardiography system, an electroencephalography system, a defibrillator, an implantable cardiac device, an electrophysiology catheter, and an ultrasound system.

8. An assembly for suppressing the induction of electromagnetic fields in an electronic device coupled to the assembly, comprising:
a paramagnetic core comprising:
an enclosure;
a paramagnetic material disposed within the enclosure; and
at least one conductive wire proximal to the surface of the paramagnetic core.

9. The assembly as recited in claim 8 in which the paramagnetic material includes a liquid solution that contains gadolinium.

10. The assembly as recited in claim 9 in which the gadolinium in the liquid solution includes at least one of a gadolinium salt and a gadolinium chelate.

11. The assembly as recited in claim 9 in which the paramagnetic material includes iron oxide particles in a suspension.

12. The assembly as recited in claim 8 in which the enclosure is a tube filled with the paramagnetic material and the at least one conductive wire is wrapped around the surface of the tube.

13. The assembly as recited in claim 8 in which the enclosure is a ring filled with the paramagnetic material and the at least one conductive wire is wrapped around the surface of the ring.

14. The assembly as recited in claim 8 in which the enclosure is an annular enclosure filled with the paramagnetic material and the at least one conductive wire extends through the center of the annular enclosure.
